(19) United States
(12) Patent Application Publication
(10) Pub. No.: US 2008/0238460 A1
(43) Pub. Date: Oct. 2, 2008

(54) Accurate alignment of semiconductor devices and sockets

(76) Inventors: Lothar Kress, Portland, OR (US); Wei-ming Chi, Gilbert, AZ (US); Pooya Tadayon, Hillsboro, OH (US)

Correspondence Address: CAVEN & AGHEVLI;c/o INTELLEVATE, LLC, P.O. BOX 52050, MINNEAPOLIS, MN, 55402, US

(21) Appl. No.: 11/731,777

(22) Filed: Mar. 30, 2007

(51) Int. Cl. G01R 31/02

(52) U.S. Cl. 324/758; 324/754; 324/755

(57) ABSTRACT

Methods and apparatus to provide accurate alignment for semiconductor sockets are described. In one embodiment, a carrier is utilized to align a device under test with a test socket. In some embodiments, alignment features on a carrier, a device under test, and/or a test socket are used to align the devices relative to each other.

### BACKGROUND

The present disclosure generally relates to the field of electronics. More particularly, an embodiment of the invention relates to accurate alignment of semiconductor devices and sockets.

As more functionality is incorporated into a single integrated circuit (IC) chip, additional pins may be provided to communicate additional signals between the chip and other components of a computing system. Chips are generally tested after fabrication to determine whether they meet the target operational requirements. Chips that include additional pins may provide the pins in a smaller foot print, e.g., to reduce packaging size or reduce manufacturing costs. However, the decreasing contact pitch may result in smaller contact areas which may not be compatible with conventional test sockets. Conventional sockets for central processing units (CPUs) and Chipsets may use the substrate edge to mechanically align the device to the socket body and as a result the device contacts to the socket pins. As these device contacts are becoming smaller, this alignment method becomes unsuitable because of substrate edge to contact array tolerances.

### BRIEF DESCRIPTION OF THE DRAWINGS

The detailed description is provided with reference to the accompanying figures. In the figures, the left-most digit(s) of a reference number identifies the figure in which the reference number first appears. The use of the same reference numbers in different figures indicates similar or identical items.

FIG. 1 illustrates a block diagram of a semiconductor testing system, according to an embodiment of the invention.

FIGS. 2-5 illustrate die views of semiconductor device alignment systems, according to some embodiments.

FIG. 6 illustrates a block diagram of a method according to an embodiment.

### DETAILED DESCRIPTION

In the following description, numerous specific details are set forth in order to provide a thorough understanding of various embodiments. However, various embodiments of the invention may be practiced without the specific details. In other instances, well-known methods, procedures, components, and circuits have not been described in detail so as not to obscure the particular embodiments of the invention. Further, various aspects of embodiments of the invention may be performed using various means, such as integrated semiconductor circuits (“hardware”), computer-readable instructions organized into one or more programs (“software”), or some combination of hardware and software. For the purposes of this disclosure reference to “logic” shall mean either hardware, software, or some combination thereof.

Reference in the specification to “one embodiment” or “an embodiment” means that a particular feature, structure, or characteristic described in connection with the embodiment may be included in at least an implementation. The appearances of the phrase “in one embodiment” in various places in the specification may or may not be all referring to the same embodiment.

Also, in the description and claims, the terms “coupled” and “connected,” along with their derivatives, may be used. In some embodiments of the invention, “connected” may be used to indicate that two or more elements are in direct physical or electrical contact with each other. “Coupled” may mean that two or more elements are in direct physical or electrical contact. However, “coupled” may also mean that two or more elements may not be in direct contact with each other, but may still cooperate or interact with each other.

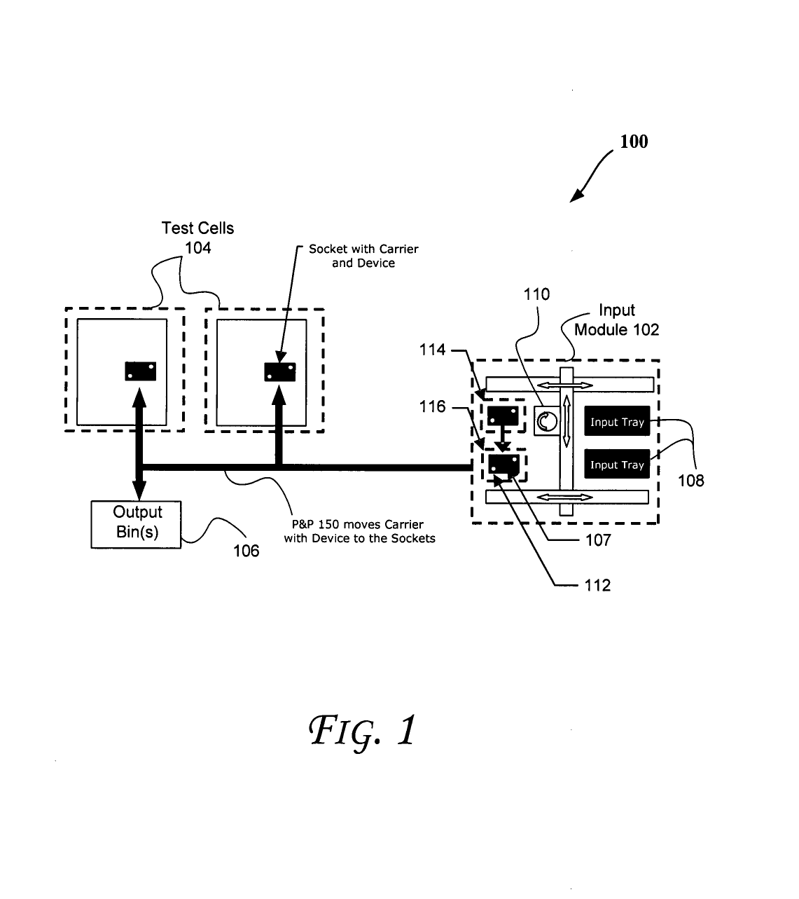

Some of the embodiments discussed herein (such as the embodiments discussed with reference to FIGS. 1-6) may utilize a carrier to facilitate alignment of a device under test (DUT) with a test socket. In some embodiments, the carrier may include a plurality of clamps to substantially reduce relative movement of the DUT and the test socket. The socket and carrier may further include alignment features in some embodiments to enable proper alignment of the DUT and the test socket during the test cycle of the DUT. Such embodiments may enable an accurate alignment system, which may allow testing of semiconductor devices with contacts or pins that may be too small for conventional test socket alignment. Further, such systems may be used to achieve relatively high parallelism in testing of semiconductor devices.

More particularly, FIG. 1 illustrates a block diagram of a semiconductor testing system 100, according to an embodiment of the invention. The system 100 may include an input module 102, one or more test cells 104, and one or more output bins 106. The input module 102 may receive one or more devices 107 that are to be tested (DUTs) via one or more input trays 108. An input pick and place (P&P) actuator 110 may move the devices 107 from the input trays 108 and place them in corresponding carriers 112. For example, an empty carrier buffer may be moved from a first (e.g., storage) location 114 to an input alignment station 116 to enable the actuator 110 to align and load the DUT 107 into the carrier 112. As shown in FIG. 1, the input P&P actuator 110 may be capable of movement in the x, y, z, and theta directions.

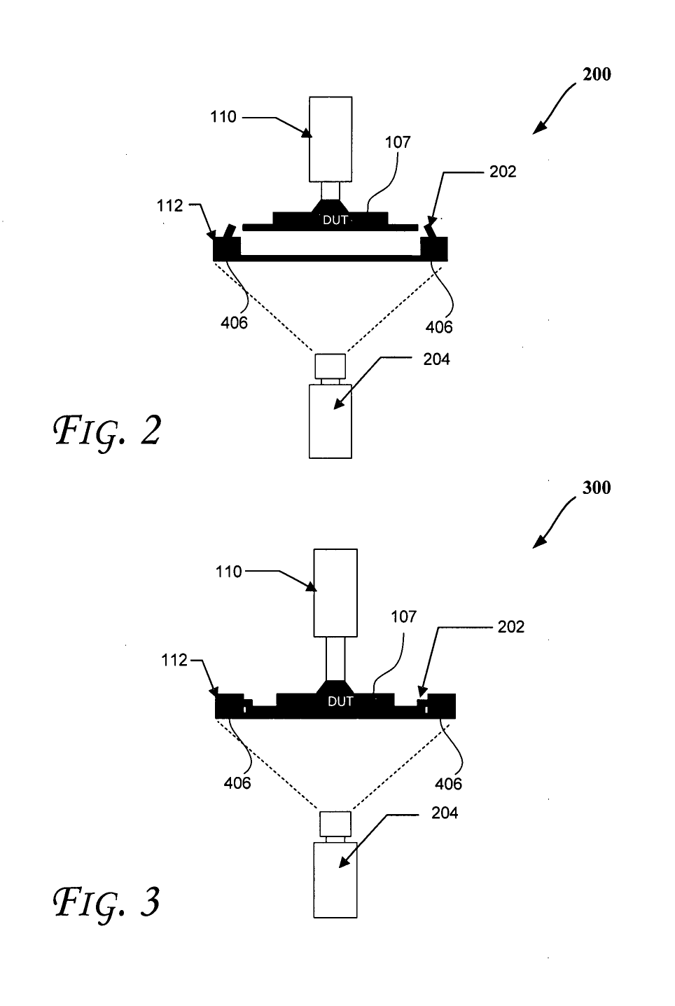

As shown in FIG. 1, after aligning the DUT 107 with the carrier 112 at alignment station 116 (e.g., by using alignment features such as those shown in FIG. 1 as white dots on the carrier 112), the carrier may be moved to one of the test cells 104 by the test site P&P actuator 150 (or alternatively by the input P&P 110). In an embodiment, alignment at the alignment station 116 may be performed with assistance from images captured from one or more cameras, as will be discussed herein, e.g., with reference to FIGS. 2 and 3. After testing at the test cells 104 is done, the carriers may be moved to corresponding output bin(s) 106 by the same P&P that moved the carriers from the input module 102 to the test cells 104 or by another P&P. In one embodiment, the test cells 104 may include sockets to receive the DUTs 107 that are carried by the carriers 112, e.g., as will be further discussed herein with reference to FIGS. 2-5.

FIG. 2 illustrates a side view of a semiconductor device alignment system 200, according to an embodiment. In one embodiment, the system 200 illustrates further details of a configuration that may be utilized at the input alignment station 116 of FIG. 1. The system 200 may include the input P&P actuator 110 that may pick (e.g., by using vacuum force) and place (e.g., by movement through x, y, z, and/or theta directions) the DUT 107 at a desired location. In the illustration of FIG. 2, the input P&P actuator may pick the DUT 107 out of the input trays 108 of FIG. 1 and place them into the socket 112 (e.g., with the aid of the camera 204). In some embodiments, the camera 204 may capture one or more images of the relative position of the DUT 107 and the carrier 112 to enable alignment of the carrier 112 and the DUT 107. Furthermore the images may capture the relative position of the device contacts to the carrier alignment features (e.g., holes 406 shown in FIGS. 2, 3, and 4) that are corresponding to the socket features. As illustrated in FIG. 2, the carrier 112 may include one or more clamps (shown in their open position).

FIG. 3 illustrates a side view of a semiconductor device alignment system 300, according to an embodiment. In one embodiment, the system 300 illustrates the system 200 of FIG. 2 after the DUT 107 is placed in the socket 112 and clamps 202 are closed. Accordingly, after the input P&P actuator 110 aligns the DUT 107 with the carrier 112 (for example with the assistance of the camera 204), the clamps 202 may be closed (such as shown in FIG. 3) to reduce relative movement of the DUT 107 and carrier 112 (e.g., locking the DUT 107 and carrier 112 together). In some embodiments, the camera 204 may capture one or more images of the relative position of the DUT 107 and the carrier 112 to verify alignment of the carrier 112 and the DUT 107. In some embodiments, the clamps 202 may be spring loaded (e.g., which may default to a locked position). Also, in an embodiment; an external device may cause opening of the clamps such as a device (that may be incorporated into a P&P such as the input P&P 110 or test site P&P 150, for example) that detects the carrier is to be or has been placed in one of the output bins 106 of FIG. 1 (e.g., after completion of testing at test cells 104 of FIG. 1). Alternatively, the position of the clamps 202 may be controlled by a device that is integrated into the carrier 112.

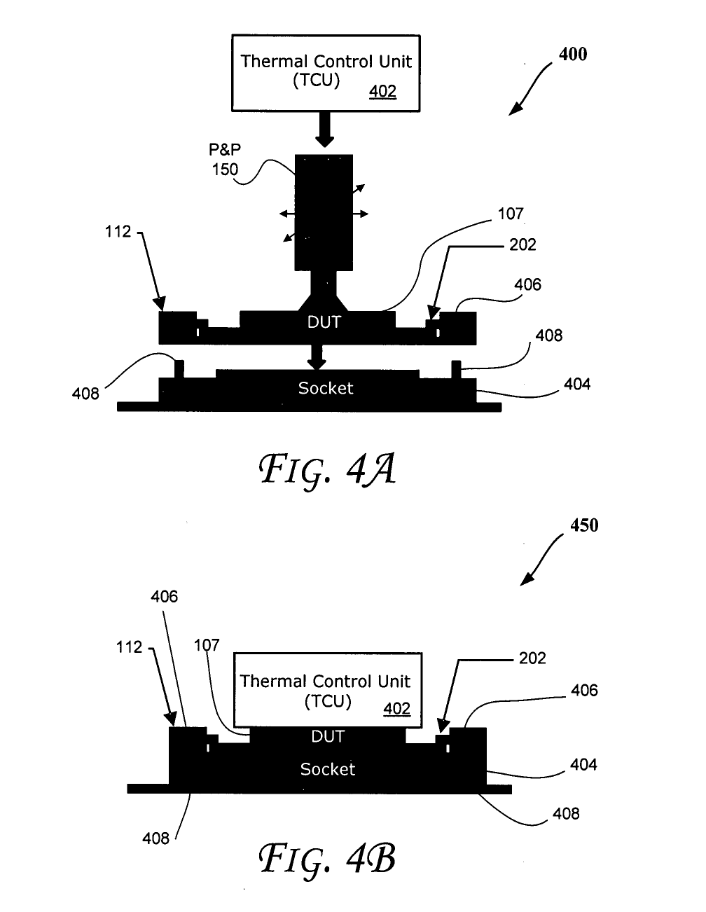

FIG. 4A illustrates a side view of a semiconductor device alignment system 400, according to an embodiment. In one embodiment, the system 400 illustrates further details of a configuration that may be utilized at the test cells 104 of FIG. 1. The system 400 may include a thermal control unit (TCU) 402 (e.g., to control the temperature of the DUT 107) and/or pick and place the DUT 107 such as discussed with reference to the test site P&P 150 of FIG. 2 or 3 (or input P&P 100). In some embodiments, the test site P&P actuator 150 of FIGS. 1-3 and the TCU 402 may apply pressure to enable engagement of various components such as the DUT 107 and carrier 112, carrier 112 and socket 404, etc. The test site P&P 150 (or input P&P 150) may align the carrier 112 (which is carrying the DUT 107 as locked in place by the clamps 202) with a socket 404 by utilizing features 406 on the carrier 112 and features 408 on the socket 404. In some embodiments, the features 406 may be holes or openings and features 408 may be pins (or vice versa). In an embodiment, a camera (not shown) may also be used to align or verify alignment of the carrier 112 and the socket 404 such as discussed with reference to FIGS. 2 and 3.

FIG. 4B illustrates a side view of a semiconductor device alignment system 450, according to an embodiment. In one embodiment, the system 450 illustrates further details of a configuration that may be utilized at the test cells 104 of FIG. 1. In some embodiments, the test site P&P 150 may release the carrier 112 and DUT 107 (e.g., after aligning with a socket 404 by utilizing features 406 on the carrier 112 and features 408 on the socket 404). The TCU 402 may apply pressure to enable engagement of the socket contacts and provide thermal control. As shown in FIG. 4B, the TCU 402 may be capable of movement in the z direction.

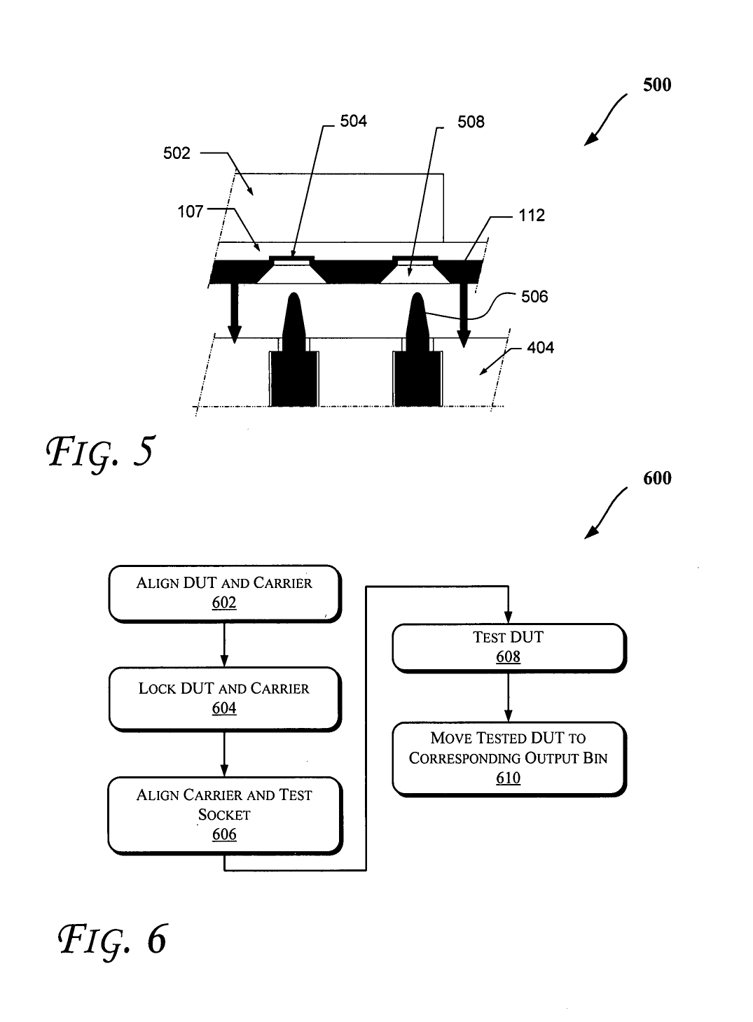

FIG. 5 illustrates a side view of a semiconductor device alignment system 500, according to an embodiment. The system 500 may include the socket 404 and DUT 107 of FIG. 4. As shown in FIG. 5, the DUT 107 may be coupled to an integrated heat spreader (IHS) 502. Also, the DUT 107 may include one or more device contacts 504 (which may also be a solder ball or pin depending on device type, for example) to receive socket pins 506 of the socket 404 via socket pin funnel holes 508 present in the carrier 112. The tapered shape of the funnel holes 508 may facilitate receipt of the pins 506 in some embodiments. The funnel holes 508 may guide the socket pins to the device contacts 504. Also, the size of the opening of the funnel holes 508 may be relatively larger than the size of the device contacts 504 to enable smaller contact areas with the same device and socket tolerances.

FIG. 6 illustrates a block diagram of an embodiment of a method 600 to align and test a DUT. In an embodiment, various components discussed with reference to FIGS. 1-5 may be utilized to perform one or more of the operations discussed with reference to FIG. 6. For example, the method 600 may be used to align and/or test the DUT 107 of FIGS. 1-5.

Referring to FIGS. 1-6, at an operation 602, a DUT and a carrier may be aligned (e.g., the DUT 107 and carrier 112 may be aligned as discussed with reference to FIGS. 1-2). At an operation 604, the DUT and carrier may be locked together (e.g., by using the clamps 202 such as discussed with reference to FIG. 3). At an operation 606, the carrier and a test socket may be aligned (e.g., the carrier 112 with the DUT 107 may be aligned with the socket 404 such as discussed with reference to FIG. 4A). At an operation 608, the DUT may be tested (e.g., the TCU 402 may apply force to engage the contacts of socket 404 with the DUT 107 such as discussed in FIG. 4B and as discussed with reference to the test cells 104 of FIG. 1). After testing the DUT at operation 608, the method 600 terminates at an operation 610 by moving the tested DUT to a corresponding output bin (e.g., such as discussed with reference to the output bins 106 of FIG. 1). Subsequently, empty carriers may be moved back into circulation, e.g., to a carrier buffer (e.g., to the location 114 of FIG. 1).

In some embodiments, techniques described herein may decrease solder resist opening (SRO) and contact pitch to enable relatively smaller devices (e.g., for mobile products) and/or a cost reduction in assembly. For example, reductions in contact pitch and SRO down to a 5-mil may be achieved. Also, a single vision alignment system (such as those discussed with reference to FIGS. 1-6) may serve a multitude of test cells for high parallelism and/or cost saving. Further, since the socket (e.g., 404) will interface to the carrier (e.g., 112) for alignment (and not to the device substrate edge, for example) the device (e.g., DUT 107) may be exposed to less stress during socket mounting and testing. Thus, the chances for damage to the device (such as die cracking) are lowered.

In various embodiments of the invention, the operations discussed herein, e.g., with reference to FIGS. 1-6, may be implemented as hardware (e.g., logic circuitry), software, firmware, or combinations thereof, which may be provided as a computer program product, e.g., including a machine-readable or computer-readable medium having stored thereon instructions (or software procedures) used to program a computer to perform a process discussed herein. The machine-readable medium may include a storage device such as those discussed with respect to FIGS. 1-6.

Additionally, such computer-readable media may be downloaded as a computer program product, wherein the program may be transferred from a remote computer (e.g., a server) to a requesting computer (e.g., a client) by way of data signals embodied in a carrier wave or other propagation medium via a communication link (e.g., a bus, a modem, or a network connection). Accordingly, herein, carrier wave shall be regarded as comprising a machine-readable medium.

Thus, although embodiments of the invention have been described in language specific to structural features and/or methodological acts, it is to be understood that claimed subject matter may not be limited to the specific features or acts described. Rather, the specific features and acts are disclosed as sample forms of implementing the claimed subject matter.

1. An apparatus comprising:
a carrier to receive a device under test (DUT); and
one or more clamps to mechanically engage the device under test to reduce relative movement of the device under test with regards to the carrier.

2. The apparatus of claim 1, further comprising an input pick and place actuator to move the device under test relative to the carrier.

3. The apparatus of claim 1, further comprising a test site pick and place actuator to move the carrier with the device under test to one or more test sites.

4. The apparatus of claim 1, further comprising a test socket to receive the carrier.

5. The apparatus of claim 4, wherein each of the socket and the carrier comprise corresponding alignment features.

6. The apparatus of claim 1, further comprising one or more cameras to capture one or more images of the relative position of the device under test and the carrier to enable alignment of the carrier and the device under test.

7. The apparatus of claim 1, wherein the carrier comprises a plurality of alignment features to facilitate alignment of the carrier alignment features and the device under test contact array at an alignment station.

8. The apparatus of claim 7, wherein the carrier comprises a plurality of funnel holes to facilitate alignment of socket contact pins to the device under test contacts.

9. The apparatus of claim 1, further comprising an integrated circuit logic to control a state of the clamps, wherein the state of the clamps is one of an open position or a closed position.

10. The apparatus of claim 1, wherein the device under test comprises one or more of: a processor, a memory device, a network communication device, or a chipset.

11. A method comprising:
aligning a device under test (DUT) and a carrier; and
engaging one or more clamps to reduce relative movement of the DUT and the carrier.

12. The method of claim 11, wherein the aligning is performed with assistance from one or more alignment features present on the DUT and the carrier.

13. The method of claim 11, further comprising aligning the carrier with a test socket.

14. The method of claim 11, further comprising providing one or more funnel holes in the carrier to assist contact alignment of a socket pin to the device.

15. The method of claim 11, further comprising capturing one or more images of the carrier and the DUT to verify alignment of the DUT and the carrier.
